(19) United States
(12) Patent Application Publication
(10) Pub. No.: US 2026/0044946 A1
(43) Pub. Date: Feb. 12, 2026

(54) ACTINIC RUN TIME SYSTEM DIAGNOSTICS OF EUV RETICLE INSPECTION AND IMAGING SYSTEMS USING MINIATURIZED EUV CALIBRATION TARGETS

(71) Applicant: KLA Corporation, Milpitas, CA (US)

(72) Inventors: Rajeev Rajendran, San Francisco, CA (US); Farid Atry, San Jose, CA (US); Rui-Fang Shi, Cupertino, CA (US)

(21) Appl. No.: 19/267,050

(22) Filed: Jul. 11, 2025

Related U.S. Application Data
(60) Provisional application No. 63/681,956, filed on Aug. 12, 2024.

(51) Int. Cl. G06T 7/00; G01N 21/33; G01N 21/956; G03F 1/22

(52) U.S. Cl. CPC G06T 7/0004; G01N 21/33; G01N 21/956; G01N 2021/95676; G03F 1/22; G06T 2207/30148; G06T 2207/30168

(57) ABSTRACT

An inspection system includes a stage for positioning a substrate to be inspected, one or more reticle-based diagnostic targets positioned on the stage, and a reticle inspection sub-system having a field of view encompassing the stage. The system includes a controller configured to move the field of view between portions of the stage to selectively perform substrate and run time diagnostics (RTD) of predefined image quality metrics. In embodiments, the system may be an APMI system for EUV mask inspection and the diagnostic targets may be EUV reticle-based diagnostic targets having predefined EUV performance patterning. In embodiments, the diagnostic targets may be positioned adjacent to the mask to be inspected to permit contiguous scanning to perform inspection and RTD.

### CROSS REFERENCE TO RELATED APPLICATION

The present application claims the benefit under 35 U.S. C. § 119(e) of U.S. Provisional Application Ser. No. 63/681,956, filed Aug. 12, 2024, which is incorporated herein by reference in its entirety.

### TECHNICAL FIELD

The present disclosure generally relates to inspection systems, and in particular, to run time diagnostics (RTD) for measuring critical inspection metrics in inspection systems.

### BACKGROUND

Actinic patterned mask inspection (APMI) tools are anchored on the principle of contiguous mask scanning across an extreme ultraviolet (EUV) field of view (FOV). In addition to achieving high static image quality, scanning systems such as APMI have the additional requirement of maintaining image performance over time (e.g., consistent performance within an inspected mask and repeatable inspection performance across multiple masks). This requirement translates to tight temporal control of critical image quality metrics. A necessary pre-requisite for control is system diagnostics of these critical imaging metrics. Run time diagnostics (RTD) of these metrics is hence the first step.

Among the myriad of system parameters that can impact EUV image quality, the critical parameters amenable to drifts and which have a direct impact on the actinic image quality include the EUV illumination pupil (EUV-P), EUV focus (EUV-F), and EUV wavefront error (EUV-WFE). For an RTD to be effective within an APMI tool, the measured system health parameters should be EUV specific, the measurements should be performed on targets having a known EUV imaging performance, the measurements should reflect the state of the system during inspection, the measurements should be periodically executed within inspections at frequencies determined by the system drift time scales, and the measurements should add minimal inspection overhead time.

Therefore, there is a need for effective methods, targets, and system architectures for RTD in inspection systems.

### SUMMARY

An inspection system is disclosed, in accordance with one or more embodiments of the present disclosure. In an illustrative embodiment, the inspection system includes a stage configured to position a substrate to be inspected, one or more diagnostic targets positioned on the stage, and a reticle inspection sub-system having a field of view encompassing the stage such that substrate inspection and run time diagnostics (RTD) can be performed on the same stage. In embodiments, the reticle inspection sub-system includes an illumination source configured to generate a beam of illumination, a first set of optical elements configured to direct the beam of illumination from the illumination source to the stage, a second set of optical elements configured to selectively magnify and image the substrate or the one or more diagnostic targets, a detector configured to detect illumination, and a controller including one or more processors. In embodiments, the controller is configured to move the field of view (by moving the stage or the optical system) between the substrate and the one or more diagnostic targets to respectively perform substrate inspection or perform RTD of predefined image quality metrics of the system.

An actinic patterned mask inspection (APMI) system is disclosed, in accordance with embodiments of the present disclosure. In an illustrative embodiment, the APMI system includes a stage configured to position an extreme ultraviolet (EUV) lithography mask to be inspected, one or more EUV diagnostic targets positioned on the stage, and an EUV reticle inspection sub-system having a field of view encompassing the stage. In embodiments, the EUV reticle inspection sub-system includes an EUV illumination source configured to generate a beam of EUV illumination, a first set of optical elements configured to direct the beam of EUV illumination from the EUV illumination source to the stage, a second set of optical elements configured to magnify and image the EUV lithography mask or the one or more EUV diagnostic targets, a detector configured to detect EUV illumination, and a controller including one or more processors. In embodiments, the controller is configured to move the field of view between the EUV lithography mask and the one or more EUV diagnostic targets to perform EUV mask inspection or perform runtime diagnostics (RTD) of predefined EUV image quality metrics.

A method for inspecting a lithography mask is disclosed, in accordance with embodiments of the present disclosure. In an illustrative embodiment, the method includes providing a mask inspection system including a stage configured to position a lithography mask to be inspected, one or more reticle-based diagnostic targets positioned on the stage, and a reticle inspection sub-system having a field of view encompassing the stage. In embodiments, the reticle inspection sub-system includes an illumination source configured to generate a beam of illumination, a first set of optical elements configured to direct the beam of illumination, a second set of optical elements configured to magnify and image the lithography mask or the one or more reticle-based diagnostic targets, and a controller including processing circuitry. In embodiments, the method includes moving, by the controller, the field of view between the lithography mask and the one or more reticle-based diagnostic targets to perform mask inspection or perform run time diagnostics (RTD) of predefined image quality metrics. In embodiments, the mask inspection may be APMI, e-Beam inspection, or optical inspection, which may be paused according to a predefined polling schedule to perform the RTD.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention, and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1 illustrates a block diagram of an inspection system such as an APMI inspection system, in accordance with one or more embodiments of the present disclosure.

FIG. 2A illustrates a stage of the inspection system and a FOV positioned for APMI inspection of a substrate, in accordance with one or more embodiments of the present disclosure.

FIG. 2B illustrates the stage of the inspection system and the FOV positioned for RTD, in accordance with one or more embodiments of the present disclosure.

FIG. 3 illustrates a reticle-based diagnostic target implemented as a calibration chip, in accordance with one or more embodiments of the present disclosure.

FIG. 4 illustrates a reticle-based diagnostic target implemented as a calibration bar, in accordance with one or more embodiments of the present disclosure.

FIG. 5 illustrates the use of a calibration chip used for performing RTD in an inspection system, in accordance with one or more embodiments of the present disclosure.

FIG. 6 illustrates the use of a calibration bar for performing RTD in an inspection system, in accordance with one or more embodiments of the present disclosure.

FIGS. 7A-7E illustrate various patterning options and combination for the RTD targets, in accordance with one or more embodiments of the present disclosure.

FIGS. 8A and 8B illustrate respective level and tilted orientations of the RTD targets, in accordance with one or more embodiments of the present disclosure.

FIG. 9 illustrates a process flow diagram for performing APMI and RTD within the same inspection tool, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

The present disclosure provides effective run time diagnostics (RTD) for inspection systems, for instance lithography mask inspection systems. In a particular conceived example, the present disclosure provides RTD for actinic patterned mask inspection (APMI) tools. In embodiments, the measured system health parameters according to the present disclosure may be EUV specific and hence may be diagnosed at EUV wavelength (e.g., 13.5 nm). In embodiments, the measurements may be performed on auxiliary RTD specific targets having a predefined EUV stack having a known EUV performance. In embodiments, the present disclosure provides a holistic system-level EUV health check involving targets at the reticle plane. For accurate measurement, the EUV targets may provide adequate reflectivity, contrast, and imaging performance at EUV wavelength. In embodiments, the EUV targets may emulate the interaction of EUV light with the EUV stack (e.g., multilayer and absorber). In embodiments, the measurements may reflect the system state during inspection by utilizing inspection-matched EUV illumination/imaging fields and pupils with the capability to perform RTD in both imaging modes of the sensor (e.g., scanning and frame), allowing emulation of APMI conditions and capturing metrics such as pupil imaging that require frame mode imaging. In embodiments, the measurements according to the present disclosure may be executed within inspection at frequencies determined by the system drift time scales.

In embodiments, a diagnostic scheme according to the present disclosure allows for periodic polling of the critical system metrics with the same field and pupil characteristics as the inspection, requires APMI level image quality on the RTD targets, provides the ability to swiftly move the system FOV between APMI and RTD using the same stage used for APMI, allows RTD polling with different architectures for low operational polling cadence sufficient to monitor slow drifts or high operational polling cadence with maximum measurement polling that can be as large as the number of swaths in inspection or at, for example, the beginning and end of each swath. In a first configuration of the RTD targets, the APMI EUV may be paused to navigate along a path (e.g., non-linear) to reach the RTD targets (e.g., miniaturized RTD targets implemented as EUV calibration chips that support step access from any swath location). In a second configuration of the RTD targets, the APMI may be paused while continuously moving along a linear imaging path to reach the RTD targets (e.g., miniaturized RTD targets implemented as elongated EUV reticle bars having a length substantially corresponding to a length of the reticle of the EUV lithography mask to allow RTD access by contiguous swath access at the beginning and/or end of each swath).

In embodiments, the diagnostic targets according to the present disclosure may be EUV reticle-based diagnostic targets fabricated to provide known and optimal imaging contrast and reflectivity at EUV wavelength (e.g., EUV RTD targets having an EUV stack). In embodiments, using a pre-engineered EUV reticle for RTD obviates the need for a customer-supplied EUV reticle and further allows system specific target pattern designs independent of the ever-changing patterns on customer-supplied EUV reticles. In embodiments, the RTD targets may be compact and have a small footprint (e.g., miniaturized), and may be positioned proximally/adjacent/contiguous to the EUV lithography mask(s) to be inspected (e.g., accessible within the available finite stroke range of the APMI stage in all degrees of freedom) to minimize disruption to the inspection process. In embodiments, the RTD targets may be pre-engineered with known EUV performance including, but not limited to, EUV pupil (EUV-P), EUV focus (EUV-F), and EUV wavefront error (EUV-WFE). In embodiments, the RTD targets may be a repository of system relevant EUV patterns (e.g., multilayer, absorber, black border, blazed black border, etc.). In embodiments, the concept of diagnostic targets for RTD may extend to non-EUV based inspection systems including, but not limited to, optical and electron-based inspection systems.

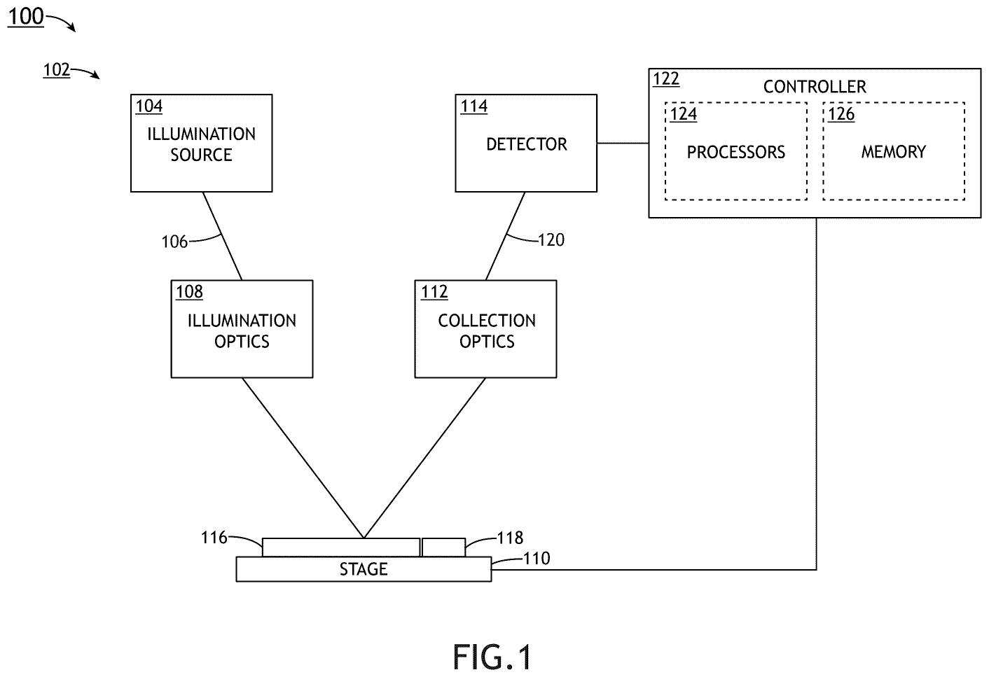

FIG. 1 schematically illustrates a lithography mask inspection system 100, in accordance with one or more embodiments of the present disclosure. In embodiments, the inspection system 100 includes a reticle inspection sub-system 102 including an illumination source 104 configured to generate a beam of illumination 106. The beam of illumination 106 may be optical and include one or more selected wavelengths of light including, but not limited to, ultraviolet (UV), deep ultraviolet (DUV), vacuum ultraviolet (VUV) radiation, extreme ultraviolet (EUV), etc. In a particular conceived example, the inspection system 100 is an actinic patterned mask inspection (APMI) system and the illumination source 104 is an EUV light source configured to generate a beam of EUV illumination (e.g., 13.5 nm). In embodiments, the inspection system 100 may be an electron beam (e-beam) inspection system in which case the illumination is electron beam.

The illumination source 104 may be any type of illumination source, e.g., optical or electron-based, known in the art suitable for generating a beam of illumination 106. In embodiments, the illumination source 104 includes a broadband plasma (BBP) illumination source that encompasses the emission in actinic wavelength or a narrow band plasma source that selectively emits at EUV such as from a synchrotron. In embodiments, the illumination source 104 may include one or more lasers capable of emitting radiation at one or more selected wavelengths. In embodiments, the illumination source 104 includes an electron beam source such as an electron gun.

In embodiments, the reticle inspection sub-system 102 includes a first set of optical elements including illumination optics 108 configured to direct the beam of illumination from the illumination source 104 to a stage 110, and a second set of optics 112 (e.g., collection optics) configured to magnify and image the illuminated substrate or one or more diagnostic target discussed in detail below. The reticle inspection sub-system 102 further includes a detector 114 configured to detect the magnified image of the illumination FOV on the substrate. In use, the optical elements are operable for at least one of directing, focusing, and shaping the beam of illumination 106. For example, the optical elements may include one or more lenses or mirrors, one or more focusing elements, etc. In embodiments, the optical elements may include any combination of reflective, transmissive, or absorbing optical elements known in the art suitable for directing and/or focusing the beam of illumination 106.

In embodiments, the stage 110 is encompassed by the field of view of the reticle inspection sub-system 102 and defines a first portion for positioning a substrate 116 (e.g., lithography mask) to be inspected and a second portion for positioning one or more diagnostic targets 118 (e.g., reticle-based diagnostic targets) as discussed in detail below. In embodiments, the stage 110 may be configured to secure in place the substrate 116 and the one or more diagnostic targets 118. The stage 110 may include any device suitable for positioning and/or scanning the substrate 116 and the one or more diagnostic targets 118 within the inspection system 100. For example, the stage 110 may include any combination of linear translation stages, rotational stages, tip/tilt stages, or the like. In alternative embodiments, the stage 110 may be fixed and the reticle inspection sub-system 102 or elements thereof may be movable relative to the stage 110, or each of the stage 110 and the reticle inspection sub-system 102 or elements thereof may be movable.

In embodiments, the detector 114 is configured to capture light/electrons emanating from the substrate 116 and the one or more diagnostic targets 118 through a collection pathway 120. The collection pathway 120 includes the second set of optics 112 (e.g., collection optics) configured to collect radiation directed from the substrate 116 and the one or more diagnostic targets 118. The second set of optics 112 may include any combination of reflective, transmissive, and absorbing optical elements known in the art suitable for directing and/or focusing the collected light. The detector 114 may include any type of detector known in the art suitable for measuring collected illumination, such as EUV light or electron beams. For example, the detector 114 may include, but is not limited to, a CCD detector, a TDI detector, a photomultiplier tube (PMT), an avalanche photodiode (APD), an electron detector, etc.

In embodiments, the inspection system 100 includes a controller 122, which may be part of the reticle-inspection sub-system 102. In embodiments, the controller 122 includes one or more processors 124 configured to execute program instructions maintained in a memory 126. In this regard, the one or more processors 124 of controller 122 may execute any of the various process steps described throughout the present disclosure. In embodiments, the controller 122 includes hardware and software elements. The controller 122 may be communicatively coupled with any component of the inspection system 100 or any additional components outside of the inspection system 100. In embodiments, the controller 122 may be configured to receive data from a component such as, but not limited to, the detector 114. For example, the controller 122 may receive any combination of raw data, processed data (e.g., inspection results), and/or partially processed data. In another embodiment, the controller 122 may perform processing steps based on the received data. For example, the controller 122 as it pertains to the lithography mask 116 may perform defect inspection steps including defect identification, classification, and sorting, and as it pertains to the one or more reticle-based diagnostic targets may measure critical imaging metrics used during inspection, for instance EUV imaging metrics including, but not limited to, EUV-P, EUV-F, and EUV-WFE. In embodiments, the controller 122 may be configured to inspect, pause inspection, move the field of view (e.g., stage translation), measure, determine, calibrate, restart inspection, etc.

In embodiments, the controller 122 may control and/or direct (e.g., via control signals) any component of the inspection system 100. For example, any combination of elements associated with the illumination pathway and/or the collection pathway may be adjustable. In this regard, the controller 122 may modify any combination of illumination conditions or imaging conditions such as, but not limited to, the illumination or imaging pupil distributions.

The inspection system 100 may be configured as any type of inspection known in the art. Further, the inspection system 100 may be, but is not required to be, an EUV inspection system 100 suitable for interrogating a substrate 116 (e.g., lithography mask) and the one or more diagnostic targets 118 with EUV light. EUV-based mask blank inspection is described generally in U.S. Pat. No. 8,711,346 to Stokowski, issued on Apr. 29, 2014, and U.S. Pat. No. 8,785,082 to Xiong et al., issued on Jul. 22, 2014, both of which are incorporated herein by reference in the entirety. In another embodiment, the inspection system 100 may be configured as a wafer inspection system or a reticle inspection system. EUV imaging is described generally in U.S. Pat. No. 8,842,272 to Wack, issued on Sep. 23, 2014, which is incorporated herein by reference in the entirety.

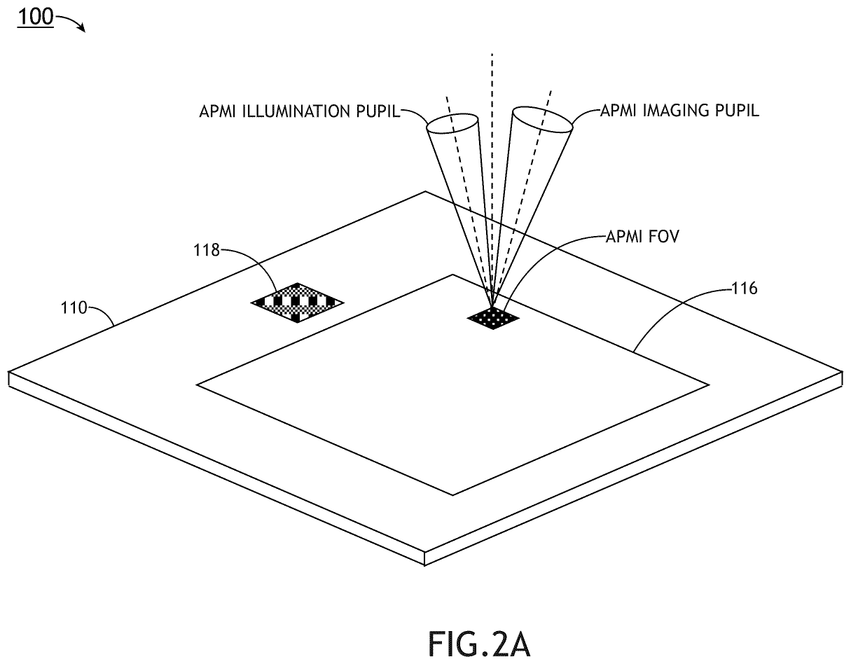

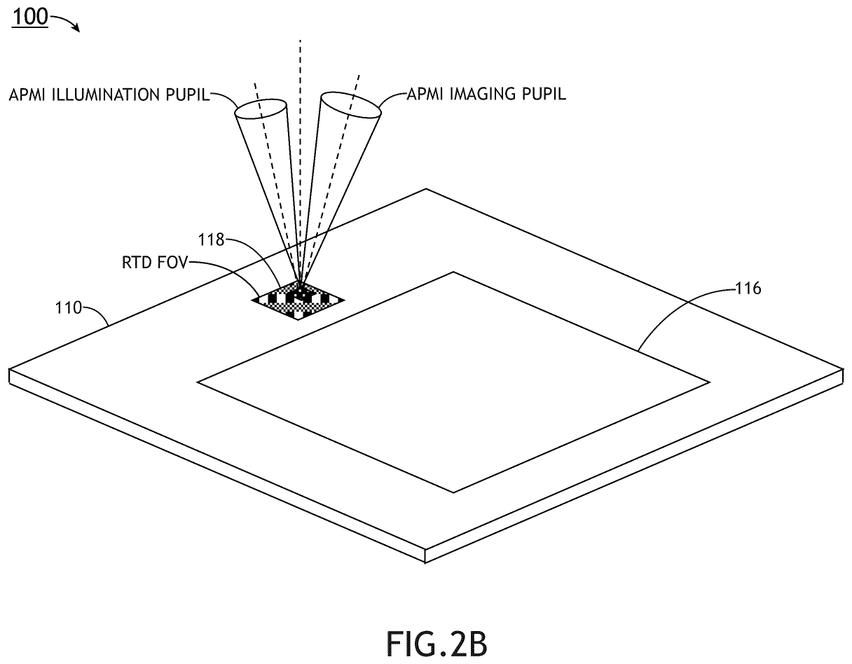

FIGS. 2A and 2B illustrate schematically the inspection system 100, and specifically the system field of view (FOV) and pupil shared and moved between substrate inspection (e.g., mask inspection) and RTD. Referring to FIG. 2A, for mask inspection such as APMI mask inspection, the system FOV and pupil are focused on the EUV reticle 200 associated with the substrate/lithography mask to be inspected. Referring to FIG. 2B, for RTD and system health check in an EUV-based system, the same FOV and pupil are moved to focus on the one or more EUV reticle-based diagnostic targets 118. In embodiments, the lithography mask and the one or more EUV reticle-based diagnostic targets 118 are positioned on the stage 110 and in close proximity such that the same FOV and pupil can be moved between the two targets to switch between APMI and RTD. In embodiments, the one or more EUV reticle-based diagnostic targets 118 preferably have a comparatively small footprint in order to share the stage and be encompassed with the system FOV.

In embodiments, the diagnostic targets 118 may be a repository of all system relevant patterns. In the case of EUV reticle-based diagnostic targets 118, the targets preferably support high contrast and high EUV photon rate and hence can be used for accurate measurements of all EUV system metrics. Non EUV-based diagnostic targets may also be utilized for non-EUV based inspection systems (e.g., optical and electron based) including, but not limited to, chrome on glass.

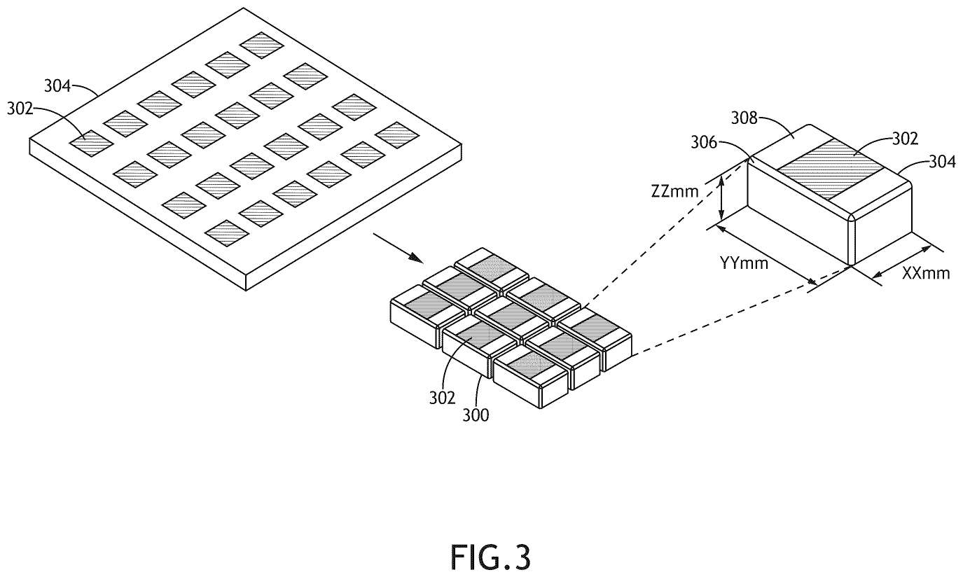

FIG. 3 illustrates EUV reticle-based diagnostic targets 118 implemented as EUV calibration chips 300 configured to support step access (e.g., x and y axis navigation) from any swath location. In embodiments, the calibration chips 300 are based on the concept of an EUV stack or derived from an industry standard EUV reticle for measuring the critical EUV imaging metrics used during inspection (e.g., EUV-P, EUV-F, EUV-WFE, etc.) and subject to drift. In embodiments, the EUV calibration chips 300 may be fabricated in mass from a patterned parent reticle 302 positioned in repeat on a substrate layer 304 which is then diced to produce a plurality of individual calibration chips 300. In embodiments, the reticle patterning 302 may be matched to the reticle patterning of the EUV substrate (e.g., lithography mask) to be inspected. Various reticle patterning can be created by combining patterning tones including, but not limited to, absorber, multilayer, black border, blazed black border, etc.

In embodiments, each calibration chip 300 may be dimensioned to position the patterned reticle 302 of the calibration chip 300 in the reticle plane of the substrate reticle and permit close spacing to the reticle substrate (e.g., lithography mask 116). For example, as it pertains to stage positioning, each calibration chip 300 may have a z axis dimension between about 6.25 mm and about 6.45 mm, and more preferably between about 6.30 mm and about 6.40 mm, may have a y axis dimension no more than about 50.0 mm, and preferably no more than about 20.0 mm, and may have an x axis dimension no more than about 50.0 mm, and preferably no more than about 20.0 mm. In embodiments, each calibration chip 300 may have chamfered edges 306 formed at the intersection of the adjacent faces and black bordering 308 positioned adjacent the reticle patterning 302 for chip clamping to the stage 110.

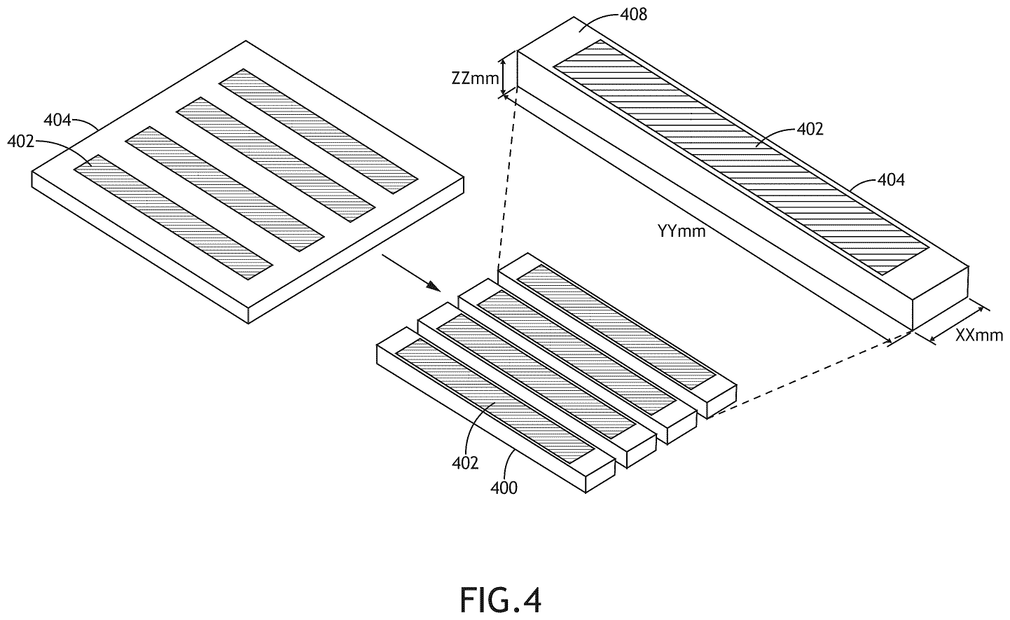

FIG. 4 illustrates EUV reticle-based diagnostic targets 118 implemented as EUV calibration bars 400 configured to support contiguous swath access. In embodiments, the calibration bars 400 are also based on the concept of an EUV stack or derived from an industry standard EUV reticle for measuring the critical EUV imaging metrics used during inspection (e.g., EUV-P, EUV-F, EUV-WFE, etc.) and subject to drift. In embodiments, the EUV calibration bars 400 may be fabricated in mass from a patterned parent reticle 402 positioned in repeat on a substrate layer 404 which is then diced to produce a plurality of individual elongated calibration bars 400. In embodiments, the reticle patterning 402 may be matched to the reticle patterning of the EUV substrate (e.g., lithography mask) to be inspected. Various reticle patterning can be created by combining patterning tones including, but not limited to, absorber, multilayer, black border, blazed black border, etc.

In embodiments, each calibration bar 400 may be dimensioned to position the patterned reticle 402 of the calibration bar 400 in the reticle plane of the substrate reticle and permit close spacing to the reticle substrate (e.g., lithography mask 116). For example, as it pertains to stage positioning, each calibration bar 400 may have a z axis dimension between about 6.25 mm and about 6.45 mm, and more preferably between about 6.30 mm and about 6.40 mm, may have a y axis dimension no more than about 150.0 mm, and preferably no more than about 130.0 mm, and may have an x axis dimension no more than about 50.0 mm, and preferably no more than about 20.0 mm (with the x axis of the stage corresponding to the swathing direction for inspection). In embodiments, each calibration bar 400 may or may not have chamfered edges formed at the intersection of the adjacent faces. In embodiments, each calibration bar 400 has black bordering 408 positioned adjacent the reticle patterning 402 for chip clamping to the stage 110.

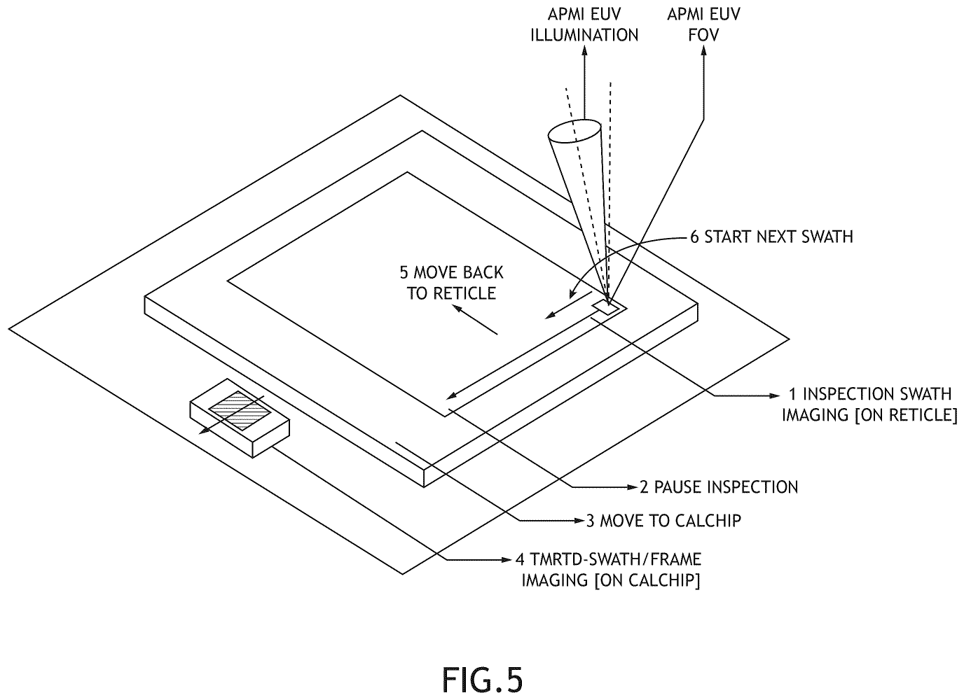

FIG. 5 illustrates schematically the use of an RTD diagnostic target implemented as a calibration chip 300 used to perform RTD in an inspection system 100, for instance an APMI system for substrate (e.g., mask) inspection. In embodiments, the substrate 500 (e.g., mask, reticle, etc.) having a surface to be inspected is secured on the stage 110 proximal to a calibration chip 300 having the predefined patterned reticle 302 of known EUV performance, and also secured on the stage 110. In embodiments, the surface to be inspected and the patterned reticle 302 of the calibration chip 300 are positioned coplanar.

During inspection, for instance during APMI inspection, swath images of a patterned zone of the substrate are taken to collect data to check for defects in the substrate. In embodiments, each image scan may correspond to a swath across the surface to be inspected, for instance along the x axis of the stage 110. Multiple swaths are typically required to image the substrate considering the comparatively small FOV of the EUV illumination. At any time during inspection, for instance between swaths or between a predefined number of swaths, the inspection may be paused to navigate the FOV to the calibration chip 300 to perform the RTD to determine the performance of the system, and particularly the measurement metrics as described above which are prone to drift over time. Depending on the disposition of the calibration chip 300 to the last swath taken, movement of the FOV to the calibration chip 300 may require stepping the x and y directions to the calibration chip 300 and then imaging the RTD target in swath in x/frame mode.

Considering the patterned reticle 302 has a known EUV performance, the collected data can be used to recalibrate the system as necessary to ensure correct/optimal performance. Once system performance has been confirmed and/or recalibrated, the FOV is returned to the patterned zone 502 for continued inspection (e.g., start the next swath). The polling frequency at which the inspection is paused and the system checked for image quality performance may correspond to the drift rates of the critical system parameters that have a direct impact on the actinic image quality (e.g., EUV-P, EUV-F, and EUV-WFE). For example, low operational polling cadence may be sufficient to monitor slow drifts whereas high operational polling cadence may be required at the beginning and/or end of each swath for maximum measurement polling.

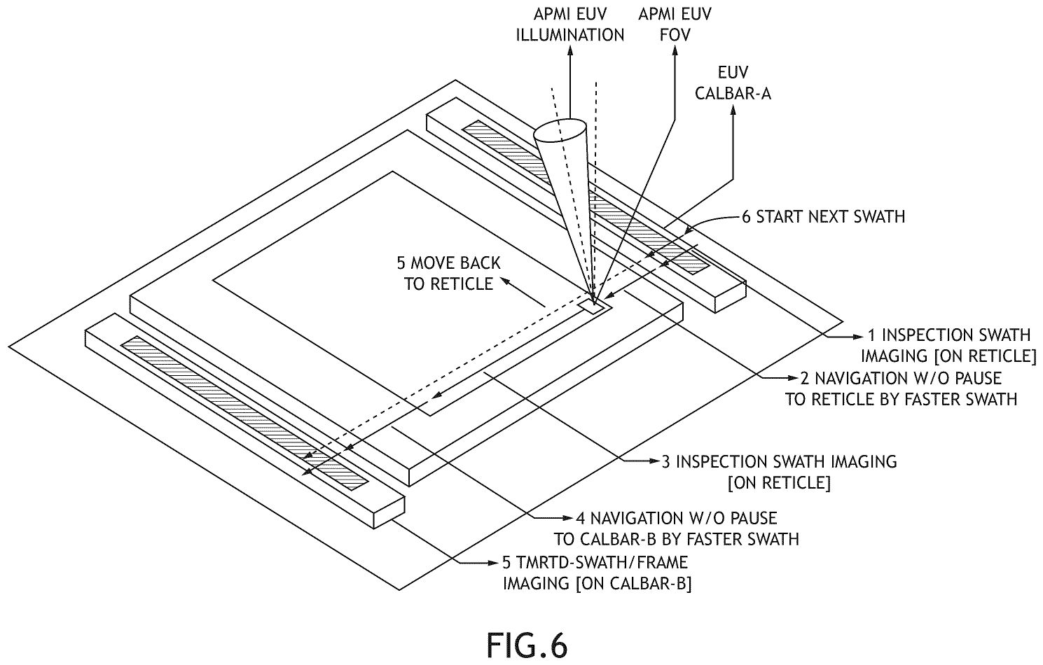

FIG. 6 illustrates schematically the use of one or more RTD targets implemented as calibration bars 400 used to perform RTD in an inspection system 100, for instance an APMI system for substrate (e.g., mask) inspection. In embodiments, the substrate 500 (e.g., mask, reticle, etc.) to be inspected is secured on the stage 110 proximal to one or more calibration bars 400, for example two calibration bars 400 positioned along opposing sides of the substrate 500 to be swath imaged along the x axis. Each calibration bar 400 has a predefined patterned reticle 402 of known EUV performance and is secured on the stage 110. In embodiments, the surface to be inspected and the patterned reticles 402 of the calibration bars 400 are positioned coplanar.

During inspection, for instance during APMI inspection, swath images of a patterned zone 502 of the substrate are taken to collect data to check for defects in the substrate. In embodiments, each image scan may correspond to a swath across the surface to be inspected, for instance along the x axis of the stage 110. Multiple swaths are typically required to image the substrate considering the comparatively small FOV of the EUV illumination. Considering the corresponding ‘lengths’ of the patterned reticle 402 and the patterned zone 502 of the substrate, contiguous swaths (e.g., along the x axis) can include surface inspection and RTD measurements. For example, for each swath, APMI can be paused while continuously moving the FOV in the along the x axis to reach the calibration bar 400 to image the patterns by swathing on the calibration bar 402 to determine system performance, and particularly the measurement metrics of the system as described above which are prone to drift over time. In the case of two calibration bars 400 positioned on opposing sides of the substrate 500, calibration swaths can be performed at the beginning and/or end of each swath in case of the need for high operational polling cadence.

Regardless of which type of RTD target is utilized, both RTD target types positioned on the same stage as the substrate 500 and in close proximity (e.g., adjacent) thereto provide the ability to swiftly move the system FOV between APMI and RTD to measure the critical system metrics (e.g., EUV system metrics) during inspection. Thus, the RTD targets perform as stand-alone miniaturized reticles and pattern repositories for system health checks, enabling RTD with the highest image contrast and reflectivity and with variable polling architectures.

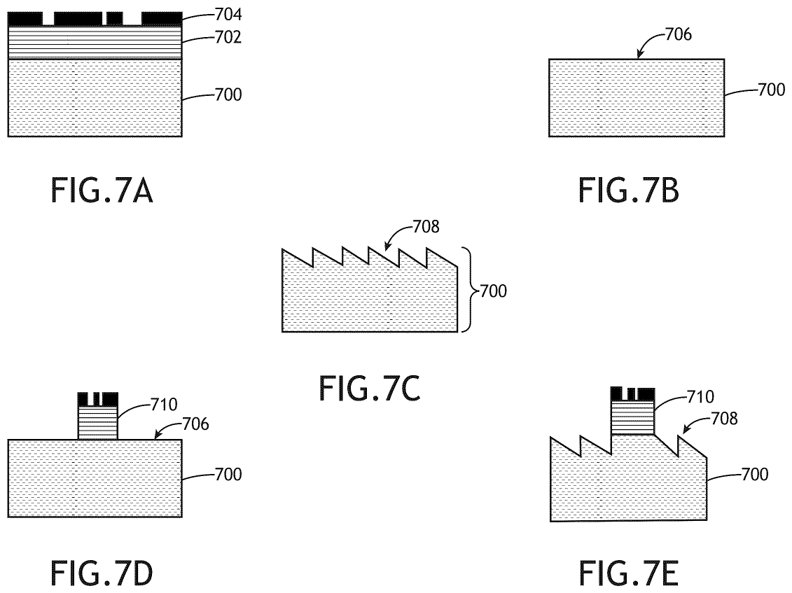

FIGS. 7A-7E illustrates various patterning (e.g., EUV patterning) for the RTD targets according to the present disclosure. In embodiments, the RTD targets may include standard and novel EUV patterns including one or more of absorber, multilayer, black border, and blazed black border patterning. FIG. 7A illustrates a standard EUV pattern including a substrate layer 700, a multilayer stack 702 disposed on the substrate layer 700, and an absorber layer 704 disposed on the multilayer stack 702. In embodiments, the multilayer stack 702 may include several alternating layers of reflective material. In embodiments, the absorber layer 704 may be configured to absorb incident illumination and/or reflective illumination. In embodiments, portions of the absorber layer 704 and/or multilayer stack 702 may be etched to form a predefined pattern.

FIG. 7B illustrates black bordering 706 for forming dark zones for EUV light that are substantially attenuated relative to patterned areas, such as the patterned areas forming selective reflection or emission of incident illumination by the multilayer stack 702 and/or absorber layer 704. Traditionally, dark zones may include areas of the substrate layer 700 that do not include a multilayer stack 702 or an absorber layer 704. Traditional black borders that rely on non-structured glass substrate for reducing intrinsic reflectivity are referred to as normal black borders (NBB), whereas black borders that rely on textured areas for reducing reflection are referred to as hybrid black borders (HBB). FIG. 7C illustrates a black border produced by gratings 708 referred to as deep black borders (DBB). In embodiments, the gratings 708 may be composed of substrate material (e.g., from the substrate layer 700) or may be formed from other material that has been applied to the surface of the substrate layer 700.

FIG. 7D illustrates an EUV patterned island 710 disposed on an NBB 706. In embodiments, the RTD targets may include a singular EUV patterned island 710 or multiple EUV patterned islands 710 positioned in spaced apart relation. In embodiments, each EUV patterned island 710 may include a multilayer stack 702 and an etched absorber layer 704. FIG. 7E illustrates an EUV patterned island 710 disposed on an NBB plateau surrounded by DBBs 708. Other configurations of RTD target patterning is envisioned. In embodiments, the EUV layers and pattern combinations may emulate the APMI EUV targe reticle.

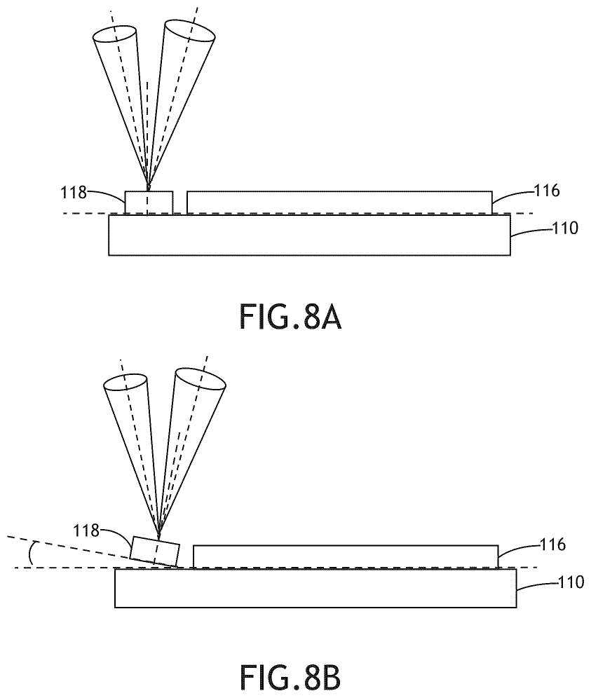

FIGS. 8A and 8B illustrate orientations of the RTD targets 118 relative to the reticle plane of the inspection system. FIG. 8A illustrates a first orientation in which the RTD target 118 (e.g., calibration chip 300 or calibration bar 400) is oriented level with the stage 110 and surface of the substrate 500 to be inspected. In embodiments, level orientation may require serial or sequential through focus measurements of the RTD target 118. FIG. 8B illustrates a second orientation in which the RTD target 118 (e.g., calibration chip 300 or calibration bar 400) is tilted relative to the stage 110 and the surface of the substrate 500 to be inspected. In embodiments, a tilted orientation may facilitate through focus capture in one continuous swath to speed throughout. In embodiments, the tilt angle may range between about 1.0 mrad and about 5.0 mrad, more preferably between about 1.0 mrad and about 3.0 mrad, and even more preferably between about 1.0 mrad and about 2.0 mrad. In some embodiments, the tilt angle is 2.0 mrad.

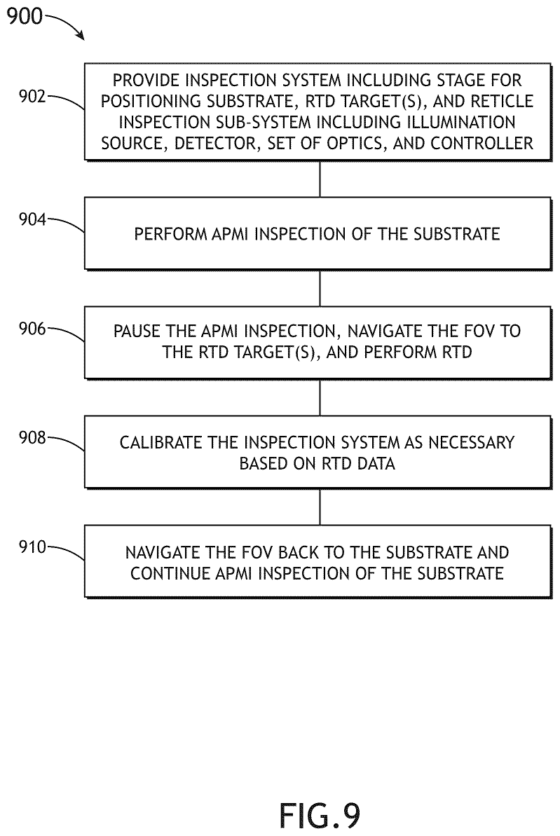

FIG. 9 illustrates a process flow diagram depicting a method 900 for performing APMI and RTD within the same inspection tool. In step 902, the method includes providing an inspection system including a stage configured to position a substrate (e.g., EUV lithography mask) to be inspected, one or more diagnostic targets positioned on the stage, and a reticle inspection sub-system having a field of view encompassing the stage, the reticle inspection sub-system including an illumination source, optical elements, a detector, and a controller. In step 904, the method includes performing APMI inspection of the substrate using the inspection tool. In step 906, the method includes pausing the APMI inspection, navigating the FOV to the one or more reticle-based diagnostic targets, and performing RTD. In step 908, the method includes calibrating the system as necessary based on data collected from the RTD. In step 910, the method includes navigating the FOV back to the substrate and continuing the APMI inspection of the substrate. In embodiments, the steps repeat as necessary to ensure system health.

In embodiments, the one or more processors 124 of the controller 122 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In embodiments, the one or more processors 124 may be embodied as a desktop computer, mainframe computer system, workstation, image computer, parallel processor, networked computer, or any other computer system configured to execute a program configured to operate or operate in conjunction with the inspection system, as described throughout the present disclosure

The memory 126 may include any storage medium known in the art suitable for storing program instructions executable by the associated one or more processors 124. For example, the memory 126 may include a non-transitory memory medium. By way of another example, the memory 126 may include, but is not limited to, a read-only memory (ROM), a random-access memory (RAM), a magnetic or optical memory device (e.g., disk), a magnetic tape, a solid-state drive and the like. It is further noted that memory 126 may be housed in a common controller housing with the one or more processors 124. In embodiments, the memory 126 may be located remotely with respect to the physical location of the one or more processors 124 and the controller 122. For instance, the one or more processors 124 of the controller 122 may access a remote memory (e.g., server), accessible through a network (e.g., internet, intranet and the like).

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components, and/or wirelessly interactable and/or wirelessly interacting components, and/or logically interacting and/or logically interactable components.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc. ” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc. ” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed:

1. An inspection system comprising:
a stage configured to position a substrate to be inspected;
one or more diagnostic targets positioned on the stage; and
a reticle inspection sub-system having a field of view encompassing the stage, the reticle inspection sub-system comprising:
an illumination source configured to generate a beam of illumination;
a first set of optical elements configured to direct the beam of illumination from the illumination source to the stage;
a second set of optical elements configured to selectively magnify and image the substrate and the one or more diagnostic targets;
a detector configured to detect illumination; and
a controller, including one or more processors, configured to move the field of view between the substrate and the one or more diagnostic targets to respectively perform inspection of the substrate or perform run time diagnostics (RTD) of predefined image quality metrics of the inspection system.

2. The inspection system of claim 1, wherein movement of the field of view between the substrate configured to be inspected and the one or more diagnostic targets includes stepped movement along an x axis and a y axis of the stage.

3. The inspection system of claim 1, wherein movement of the field of view between the substrate configured to be inspected and the one or more diagnostic targets includes contiguous swath movement along an x axis of the stage.

4. The inspection system of claim 1, comprising a single diagnostic target positioned along one side of an area defined on the stage configured to position the substrate.

5. The inspection system of claim 1, comprising two diagnostic targets positioned on opposing sides of an area defined on the stage configured to position the substrate.

6. The inspection system of claim 1, wherein the one or more diagnostic targets are positioned proximal to the substrate configured to be inspected to allow inspection and RTD of the predefined image quality metrics to be performed in one or more contiguous swaths.

7. The inspection system of claim 1, wherein the one or more diagnostic targets are implemented as calibration chips.

8. The inspection system of claim 1, wherein the one or more diagnostic targets are implemented as calibration bars.

9. The inspection system of claim 1, wherein the inspection system is an actinic patterned mask inspection (APMI) system, the substrate is an extreme ultraviolet (EUV) lithography mask, the one or more diagnostic targets are EUV reticle-based diagnostic targets, and the predefined image quality metrics include one or more of EUV illumination pupil (EUV-P), EUV focus (EUV-F), and EUV wavefront error (EUV-WFE).

10. The inspection system of claim 9, wherein the EUV reticle-based diagnostic targets are stack-matched to the EUV lithography mask configured to be inspected.

11. The inspection system of claim 9, wherein the EUV reticle-based diagnostic targets comprise predefined EUV performance patterning including at least one of a multilayer stack, an absorber, a black border, a blazed black border, EUV pattern islands positioned on black border, and EUV pattern islands positioned on blazed black border.

12. The inspection system of claim 1, wherein the one or more diagnostic targets are positioned level with the stage.

13. The inspection system of claim 1, wherein the one or more diagnostic targets are tilted relative to the stage.

14. The inspection system of claim 13, wherein a tilt angle of the one or more diagnostic targets is between 1.0 mrad and 5.0 mrad.

15. The inspection system of claim 1, wherein the controller is configured to poll the RTD according to drift times of the predefined image quality metrics of the inspection system.

16. An actinic patterned mask inspection (APMI) system comprising:
a stage configured to position an extreme ultraviolet (EUV) lithography mask to be inspected;
one or more EUV reticle-based diagnostic targets positioned on the stage; and
an EUV reticle inspection sub-system having a field of view encompassing the stage, the EUV reticle inspection sub-system comprising:
an EUV illumination source configured to generate a beam of EUV illumination;
a first set of optical elements configured to direct the beam of EUV illumination from the EUV illumination source to the stage;
a second set of optical elements configured to selectively magnify and image the EUV lithography mask and the one or more EUV reticle-based diagnostic targets;
a detector configured to detect EUV illumination; and
a controller, including one or more processors, configured to move the field of view between the EUV lithography mask and the one or more EUV reticle-based diagnostic targets to respectively perform APMI inspection and perform run time diagnostics (RTD) of predefined image quality metrics of the APMI system.

17. The APMI system of claim 16, wherein movement of the field of view between the EUV lithography mask configured to be inspected and the one or more EUV reticle-based diagnostic targets includes stepped movement along an x axis and a y axis of the stage.

18. The APMI system of claim 16, wherein movement of the field of view between the EUV lithography mask configured to be inspected and the one or more EUV reticle-based diagnostic targets includes contiguous swath movement along an x axis of the stage.

19. The APMI system of claim 16, comprising a single EUV reticle-based diagnostic target position along one side of an area defined on the stage configured to position the EUV lithography mask.

20. The APMI system of claim 16, comprising two EUV reticle-based diagnostic targets positioned on opposing sides of an area defined on the stage configured to position the EUV lithography mask.

21. The APMI system of claim 16, wherein the one or more EUV reticle-based diagnostic targets are positioned proximal to the EUV lithography mask configured to be inspected to allow EUV lithography mask inspection and the RTD pf the predefined EUV image quality metrics to be performed in one or more contiguous swaths.

22. The APMI system of claim 16, wherein the one or more EUV reticle-based diagnostic targets are implemented as calibration chips.

23. The APMI system of claim 16, wherein the one or more EUV reticle-based diagnostic targets are implemented as calibration bars.

24. The APMI system of claim 16, wherein the one or more EUV reticle-based diagnostic targets are stack-matched to the EUV lithography mask configured to be inspected.

25. The APMI system of claim 16, wherein the EUV reticle-based diagnostic targets comprise predefined EUV performance patterning including at least one of a multilayer stack, an absorber, a black border, a blazed black border, EUV pattern islands positioned on black border, and EUV pattern islands positioned on blazed black border.

26. The APMI system of claim 16, wherein the one or more EUV reticle-based diagnostic targets are positioned level with the stage.

27. The APMI system of claim 16, wherein the one or more EUV reticle-based diagnostic targets are tilted relative to the stage.

28. The APMI system of claim 27, wherein a tilt angle of the one or more EUV reticle-based diagnostic targets is between 1.0 mrad and 5.0 mrad.

29. The APMI system of claim 16, wherein the controller is configured to poll the RTD according to drift times of the predefined image quality metrics of the APMI system.

30. A method for inspecting a lithography mask, the method comprising:
providing a mask inspection system comprising:
a stage configured to position a lithography mask to be inspected;
one or more diagnostic targets positioned on the stage; and
a reticle inspection sub-system having a field of view encompassing the stage, the reticle inspection sub-system comprising an illumination source configured to generate a beam of illumination, optical elements, a detector configured to detect the beam of illumination, and a controller including one or more processors;
moving, by the controller, the field of view relative to the stage to image the lithography mask to perform lithography mask inspection; and
moving, by the controller, the field of view relative to the stage to image the one or more diagnostic targets to perform run time diagnostics (RTD) of predefined image quality metrics.

31. The method according to claim 30, wherein movement of the field of view includes movement along an x axis and a y axis of the stage.

32. The method of claim 30, wherein movement of the field of view includes movement along an x axis of the stage.

33. The method of claim 30, wherein:
the mask inspection system is an actinic patterned mask inspection (APMI) system;
the one or more diagnostic targets are extreme ultraviolet (EUV) reticle-based diagnostic targets;
the lithography mask is an EUV lithography mask;
the illumination source is an EUV illumination source; and
the predefined image quality metrics are predefined EUV image quality metrics including at least one of EUV illumination pupil (EUV-P), EUV focus (EUV-F), and EUV wavefront error (EUV-WFE).

34. The method of claim 30, wherein the controller is configured to move the field of view in one or more contiguous swaths across the stage.

35. The method of claim 30, wherein the one or more diagnostic targets are implemented as chips or elongated bars.

36. The method of claim 30, wherein the one or more diagnostic targets comprise predefined performance patterning including at least one of a multilayer stack, an absorber, a black border, a blazed black border, pattern islands positioned on black border, and pattern islands positioned on blazed black border.

37. The method of claim 30, wherein the one or more diagnostic targets are tilted relative to the stage at a tilt angle between 1.0 mrad and 5.0 mrad.

38. The method of claim 30, further comprising polling, by the controller, the RTD according to drift times of the predefined image quality metrics.
